(19) United States
(12) Patent Application Publication
(10) Pub. No.: US 2021/0403751 A1
(43) Pub. Date: Dec. 30, 2021

(54) POLYIMIDE MATERIAL, PREPARING METHOD THEREOF, AND USE THEREOF

(71) Applicant: WUHAN CHINA STAR OPTOELECTRONICS SEMICONDUCTOR DISPLAY TECHNOLOGY CO., LTD., Wuhan (CN)

(72) Inventor: Yamin WANG, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/649,855

(22) PCT Filed: Nov. 22, 2019
(86) PCT No.: PCT/CN2019/120216

§ 371 Date: Mar. 23, 2020

(30) Foreign Application Priority Data
Sep. 24, 2019 (CN) 201910902459.3

(51) Int. Cl. C09D 179/08; C08G 73/10; H01L 51/00

(52) U.S. Cl. CPC C09D 179/08; C08G 73/1071; C08G 73/1053; H01L 2251/5338; C08G 73/1042; C08G 73/1032; H01L 51/0097; C08G 73/1039

(57) ABSTRACT

A polyimide material, a preparing method thereof, and a use thereof are provided. The polyimide material employs a newly introduced 2,4-trifluoromethyl dianhydride with benzene rings and fluorine-containing p-phenylenediamine, and the phenylenediamine with the simple binding structure is used to design a molecular structure of a target polyimide material compound. A polyimide material is provided. By introducing a new molecular structure containing a dianhydride structure with fluorine and benzene rings, and combining a diamine structure, the target polyimide material with a low coefficient of thermal expansion (CTE) performance parameter is obtained.

The present disclosure claims priority to china application No. 201910902459.3 entitled “a polyimide material, a preparing method thereof, and a use thereof” filed to China National Intellectual Property Administration (CNIPA) on Sep. 24, 2019, the entire contents of which are incorporated by reference herein.

### FIELD OF INVENTION

The present disclosure relates to the field of display panel technology, and in particular, to a polyimide material, a preparing method thereof, and a use thereof.

### BACKGROUND OF INVENTION

Currently, a plurality of new optoelectronic devices, such as organic light-emitting diode (OLED) panels and solar panels, are known to be developed in a flexible, light, and thin direction.

The appearance of flexible electronic products may bring a great change to human-computer interaction (HCl). But before that, many technical obstacles still require to be overcome one by one. The flexibility of the devices significantly depends on material of substrates. For example, in the OLED field, it is known that the flexible substrates and a vapor deposition technology are two main points which are hard to be overcome in the industry.

Although conventional polyimide (PI) material has a low coefficient of thermal expansion due to a rigid straight-chain structure thereof, the low coefficient of thermal expansion possibly causes problems in mechanical performance and transmittance performance. Currently, studies of the industry on the above-mentioned issues are in application bottleneck. Since 2015, people have envisaged using the PI material to be material of the flexible substrates, and studies of applications of the PI have begun to aim at: reducing the coefficient of thermal expansion as much as possible, and achieving desirable transmittance and the mechanical performance.

Furthermore, the coefficient of thermal expansion of the PI is within one hundred orders of magnitude, and there is a small difference in orders of magnitude between the coefficient of thermal expansion of the PI and the coefficient thermal expansion of inorganic material, such as glass and silicon. However, the PI used as the material of the substrate requires to be provided with various functional layers thereon, such that the PI inevitably requires to be bonded to various types of metal, silicon, and other materials. In this case, the coefficients of thermal expansion (CTE) of the bonded materials are required to be close to each other.

Specifically, for example, the CTE of copper is about 18 ppm/K, and the CTE of silicon is about 3 ppm/K, so a range of variation of the CTEs between copper and silicon is great. Moreover, the bonded materials per se are further required to have parameter indicators, such as sufficiently high mechanical support strength and high insulation.

### SUMMARY OF INVENTION

An aspect of the present disclosure provides a polyimide material. By introducing a new molecular structure containing a dianhydride structure with fluorine and benzene rings, and combining a diamine structure, a designed target polyimide material compound may not only realize its own highly regular arrangement, but also facilitate coordinated arrangement of the diamine molecules, thus rendering molecular chains of the target compound compact, to achieve close packing between the molecular chains. Therefore, the regular structure of the molecular chains realizes the target compound with a low coefficient of thermal expansion (CTE) performance parameter.

### Technical Solutions

The present disclosure employs the technical solutions as follows:

A polyimide material comprising a structural formula as shown in the following:

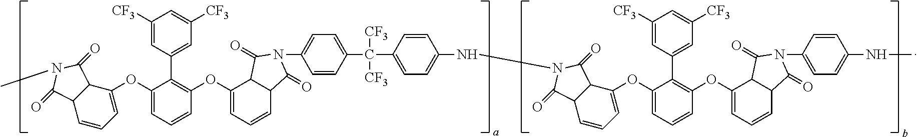

Furthermore, in different embodiments, the polyimide material is obtained from its precursor polyamic acid (PAA) through dehydration and cyclization treatment, and a structural formula of the precursor polyamic acid is:

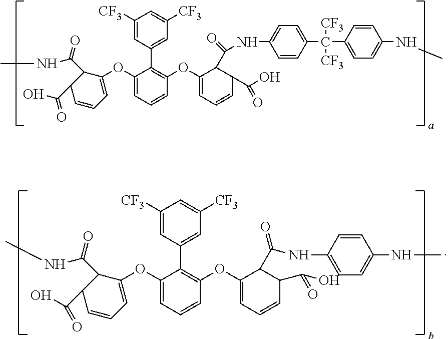

Furthermore, in different embodiments, the polyamic acid is prepared by raw materials including 3,5-trifluoromethyl-p-1,3-diether-diphthalic anhydride (referred to a compound A for the convenience of below description), 2,4-trifluoromethyl-p-aniline (referred to a compound B for the convenience of below description), and phthalic anhydride (referred to a compound C for the convenience of below description).

Furthermore, in different embodiments, a structural formula of the compound A is:

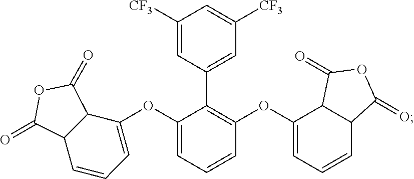 [SMILES: O=C1OC(=O)C2C(Oc3cccc(OC4=CC=CC5C(=O)OC(=O)C45)c3-c3cc(C(F)(F)F)cc(C(F)(F)F)c3)=CC=CC12]

Furthermore, in different embodiments, a structural formula of the compound B is:

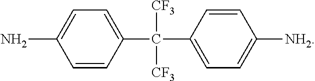 [SMILES: Nc1ccc(C(c2ccc(N)cc2)(C(F)(F)F)C(F)(F)F)cc1]

Furthermore, in different embodiments, a structural formula of the compound C is:

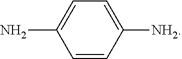

Furthermore, in different embodiments, a molar ratio of the compound A, the compound B, and the compound C is that a molar concentration of the compound A is equal to a sum of a molar concentration of the compound B and a molar concentration of the compound C.

Furthermore, in different embodiments, a molar ratio of the compound B and the compound C is a:b ranging from 0:10 to 10:0, and wherein 0≤a≤10, 0≤b≤10, and a+b=10. A specific molar ratio of the compound B and the compound C may be, but not limited to, 0:10, 1:9, 3:7, 4:6, 5:5, 6:4, 7:3, 8:2, 9:1, 10:0, etc.

On the other hand, in some cases, the precursor polyamic acid of the polyimide material involved in the present disclosure is prepared by the materials which may be one of the compound B and the compound C, rather than the mixture of the compound B and the compound C. However, in other cases, the preparation materials preferably include both of the compound B and the compound C, that is, the concentration of the compound B and the concentration of the compound C are greater than zero. For example, a ratio of the compound B and the compound C is a:b, and wherein 0<a<10, 0<b<10, and a+b=10.

Moreover, another aspect of the present disclosure provides a preparing method for the polyimide material involved in the present disclosure, and the preparing method includes following steps:

a step S1 of providing preparation raw materials including a compound A which is 3,5-trifluoromethyl-p-1,3-diether-diphthalic anhydride and a compound B which is 2,4-trifluoromethyl-p-aniline, and adding the compound A and the compound B into a mixture of N, N-dimethylhexanamide and N-methylpyrrolidone to form a first mixture solution, followed by starting to stir; providing a compound C which is phthalic anhydride, and adding the compound C into the first mixture solution during stirring to form a second mixture solution; and then continuing stirring at 20-40° C. for 24-96 hours to be fully dissolved;

a step S2 of suction-filtrating the second mixture solution in a vacuum environment, vacuum evacuating a solution obtained after suction-filtrating for 0.8-1.5 hours, removing bubbles in the solution, and then standing the solution at room temperature for 2-4 hours after evacuating, thus obtaining a solution containing precursor polyamic acid; and

a step S3 of dehydrating the solution containing the precursor polyamic acid, and cyclizing the precursor polyamic acid, thus obtaining the polyimide material involved in the present disclosure.

Moreover, in different embodiments, in the step S1, a volume ratio of the mixture of the N, N-dimethylhexanamide (DMAC) and the N-methylpyrrolidone (NMP) is 0.2 to 2, that is, DMAC/NMP=v/v=0.2-2.

Furthermore, another aspect of the present disclosure provides a use of the polyimide material involved in the present disclosure. The polyimide material is used to constitute a polyimide film layer disposed on a substrate, and the substrate may be, but not limited to, a glass substrate in general.

Moreover, another aspect of the present disclosure provides a preparing method for preparing a polyimide film layer on a glass substrate by using the polyimide material involved in the present disclosure, and the preparing method includes following steps:

a step S1 of providing the precursor polyamic acid solution obtained from the preparing method for the polyimide material involved in the present disclosure, and coating the precursor polyamic acid on a glass substrate;

a step S2 of performing a high temperature-vacuum dry (H-VCD) process on the glass substrate under a temperature ranging from 110° C. to 130° C. to remove 55% to 75% of solvent in the polyamic acid solution coated on the glass substrate; and then heating the glass substrate and performing a constant temperature recipe under a maximum temperature ranging from 400° C. to 500° C. to allow the polyamic acid coated on the glass substrate to undergo a dehydration and cyclization reaction, thereby being cross-linked and cured to finally obtaining the polyimide film layer forming on the glass substrate.

Moreover, in the step S2, the constant temperature recipe is performed on the polyamide acid for 3-5 hours, that is, the cross-linking and curing process of the polyamic acid continues for 3-5 hours, and wherein a heating rate is 4-10° C. per hour and a maximum temperature is within a range from 420° C. to 500° C.

Furthermore, another aspect of the present disclosure provides a use of the polyimide material involved in the present disclosure. The polyimide material serves as a material constituting a substrate layer on a polyimide (PI) substrate. Moreover, the PI substrate involved in the present disclosure may be used for devices which are made up of polyimide film layers, for example, but not limited to, optoelectronic devices.

Moreover, the other aspect of the present disclosure provides a use of the substrate layer involved in the present disclosure. The substrate layer is used for a display panel. The display panel includes the substrate layer provided with a device functional layer. Specifically, the display panel may be, but not limited to, an organic light-emitting diode (OLED) display panel.

### Advantageous Effects

In comparison with conventional technology, the advantageous effects of the present disclosure are: a polyimide material involved in the present disclosure employs a newly introduced 2,4-trifluoromethyl dianhydride with benzene rings and fluorine-containing p-phenylenediamine, and the phenylenediamine with the simple binding structure is used to design a molecular structure of a target polyimide material compound. The fluorine-containing group introduced in the molecular structure of the target compound may not only reduce intermolecular force, but also destroy close packing of the polymer to reduce crystallization performance of the polymer, thereby efficiently improving transmittance performance; besides, the fluorine-containing group may also be used to adjust a rigid structure of a main chain.

Furthermore, the diamine structures with different compactness degrees are obtained by implementing six proportion protocols of the diamine with different contents in the preparation raw materials, thereby obtaining a relation between the coefficient of thermal expansion and the main chain structure of the target compound. By obtaining the correlation between the coefficient of thermal expansion of the target compound and the rigid structure of the molecular chains, not only may the highly regular arrangement of the target compound be realized, but also the coordinated arrangement of the two diamine molecules may be facilitated, thus rendering the molecular chains compact, to achieve the close packing between the molecular chains. Therefore, the regular structure of the molecular chains of the target compound allows the material per se to present the relatively low CTE in the CTE performance parameter.

In summary, the dianhydride containing fluorine and benzene rings is selected to be the preparation raw material of the target compound material involved in the present disclosure, thus realizing desirable transmittance of the final material and improving the mechanical performance of the final material, so that the final material is effectively used for the OLED substrate layer. However, it should be understood that the polyimide material involved in the present disclosure is not limited to be used for the OLED substrate. The polyimide material may be used for a variety of suitable applications, as long as the performance parameters of the target compound obtained according to different proportion of the raw materials conform to requirements of the applications.

### DESCRIPTION OF DRAWINGS

In order to clearly illustrate technical solutions in embodiments of the present disclosure, the drawings required for using in the description of the embodiments is briefly described below. Obviously, the drawings in the following description are only some of the embodiments of the present disclosure. For those skilled in the art, other drawings may also be obtained in accordance with these drawings without making for creative efforts.

FIG. 1 is a structural schematic view of a polyimide (PI) substrate provided by an embodiment of the present disclosure.

FIG. 2 is a process schematic view of a constant temperature recipe provided by an embodiment of the present disclosure.

FIG. 3 is a process schematic view of a constant temperature recipe provided by another embodiment of the present disclosure.

FIG. 4 is a process schematic view of a constant temperature recipe provided by another embodiment of the present disclosure.

FIG. 5 is a process schematic view of a constant temperature recipe provided by the other embodiment of the present disclosure.

FIG. 6 is curves of coefficients of thermal expansion of target compounds of the polyimide material involved in the present disclosure obtained from different proportion of raw materials.

FIG. 7 is stress strain curves of the target compounds of the polyimide material involved in the present disclosure obtained from the different proportion of raw materials as shown in FIG. 6.

### DETAILED DESCRIPTION OF PREFERRED EMBODIMENTS

A polyimide material, a preparing method thereof, and a use thereof are described in detail in combination with drawings and embodiments below.

The present disclosure involves in a structure of a polyimide material and a preparing method thereof. To avoid unnecessary repetitive description and to clearly illustrate, the structure of the polyimide material involved in the present disclosure is illustrated in detail by mainly illustrating the preparing method below.

An embodiment of the present disclosure provides a method for preparing the polyimide material involved in the present disclosure, and the method includes following steps:

a step S1 of providing preparation raw materials including a compound A which is 3,5-trifluoromethyl-p-1,3-diether-diphthalic anhydride and a compound B which is 2,4-trifluoromethyl-p-aniline, and adding the compound A and the compound B into a mixture (DMAC/NMP=v/v=0.2-2) of N-dimethylhexanamide (DMAC) and N-methylpyrrolidone (NMP) to form a first mixture solution, followed by starting to stir, providing a compound C which is phthalic anhydride, adding the compound C into the first mixture solution during stirring to form a second mixture solution, and then continuing stirring at 20-40° C. for 24-96 hours, so that the mixture is fully dissolved;

a step S2 of suction-filtrating the second mixture solution in a vacuum environment, evacuating a solution obtained after suction-filtrating by a vacuum pump for 1 hours, removing bubbles in the second mixture solution, and then standing the solution at room temperature for 2-4 hours after evacuating to further decrease the bubbles until no bubbles visualized by naked eyes, thus obtaining a solution containing precursor polyamic acid (the precursor polyamic acid is referred to as a compound D); and

a step S3 of dehydrating the solution containing the precursor polyamic acid, and cyclizing the precursor polyamic acid, thus obtaining the target compound of the polyimide material involved in the present disclosure (referred to a compound E).

In this case, by combining the process in which the polyimide material involved in the present disclosure forms a polyimide layer (PI layer) on a glass substrate, the process of dehydrating and cyclizing the above precursor polyamic acid solution is described in detail.

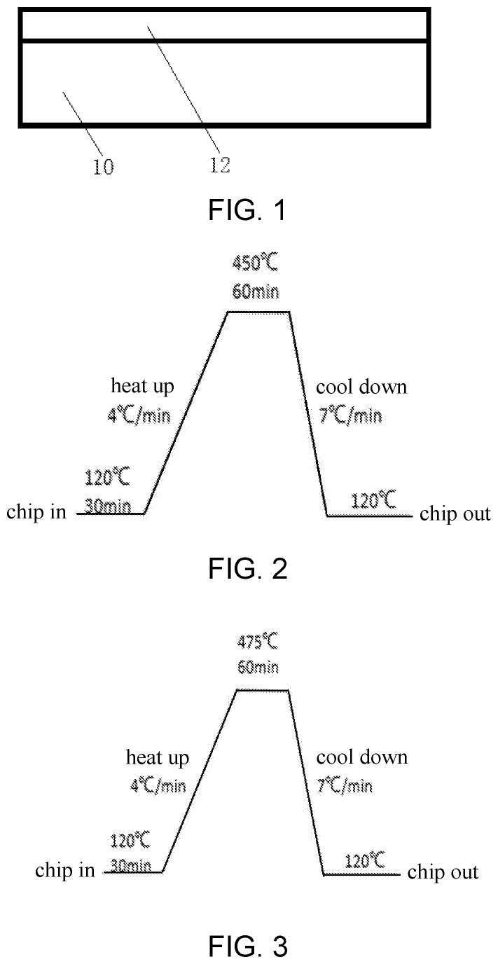

Specifically, the precursor polyamic acid solution obtained from the step 2 is spin-coated on a glass substrate 100 by a slit coater. Then, a high temperature-vacuum dry (H-VCD) process is performed on the glass substrate under a temperature ranging from 110° C. to 130° C. to remove about 70% of solvent in the polyamic acid solution coated on the glass substrate. Next, the glass substrate is heated and treated with a constant temperature recipe under a maximum temperature ranging from 400° C. to 500° C. to allow the polyamic acid coated on the glass substrate 100 to undergo the dehydration and cyclization reaction, thereby being cross-linked and cured to finally obtaining the polyimide film layer 12 forming on the glass substrate 100. The final structure is as shown in FIG. 1.

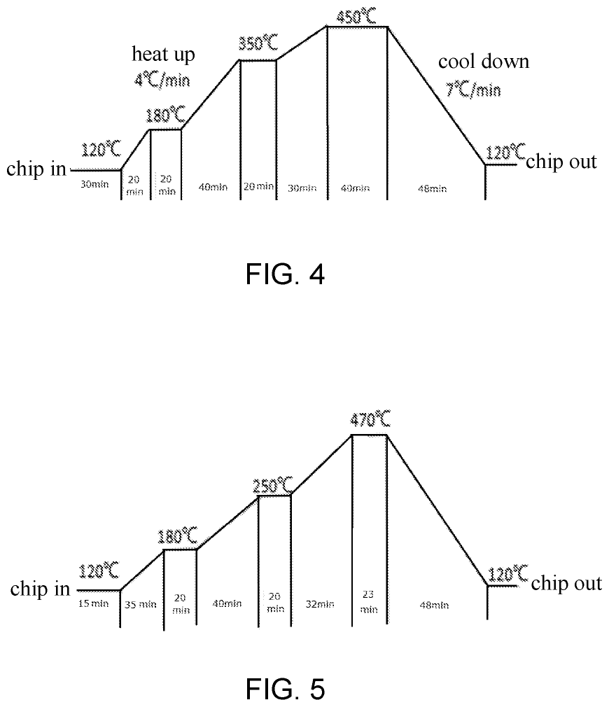

In this case, the constant temperature recipe is performed on the polyamic acid for 3-5 hours. That is, the cross-linking and curing process of the polyamic acid continues for 3-5 hours, and wherein a heating rate is 4-10° C. per hour and a maximum temperature is within a range from 420° C. to 500° C. during the constant temperature process. Furthermore, a baking stage during the constant temperature are divided into two types, which are hard baking and soft baking. The hard baking is to directly increase a temperature to a maximum temperature and keep the maximum temperature at a constant temperature for about 1 hour, followed by lowering the temperature. The soft baking includes two or more constant temperature platforms, and the constant temperature of each of constant temperature platforms is increased sequentially. That is, a constant temperature of a second constant temperature platform is higher than a constant temperature of a first constant temperature platform, and then the temperature is lowered. Thus, the precursor polyamic acid is cross-linked at different constant temperature stages, and the solvent is removed therefrom. Four different constant temperature platforms are shown in FIG. 2 to FIG. 5, but are not limited thereto.

Furthermore, according to creative concepts of the present disclosure, it is known that there is a proportion of the compound B and the compound C in the preparation raw materials of the precursor polyamic acid, and a correlation between a coefficient of thermal expansion of the target compound of the precursor polyamic acid involved in the present disclosure and a rigid structure of molecular chains is obtained by different proportion protocols.

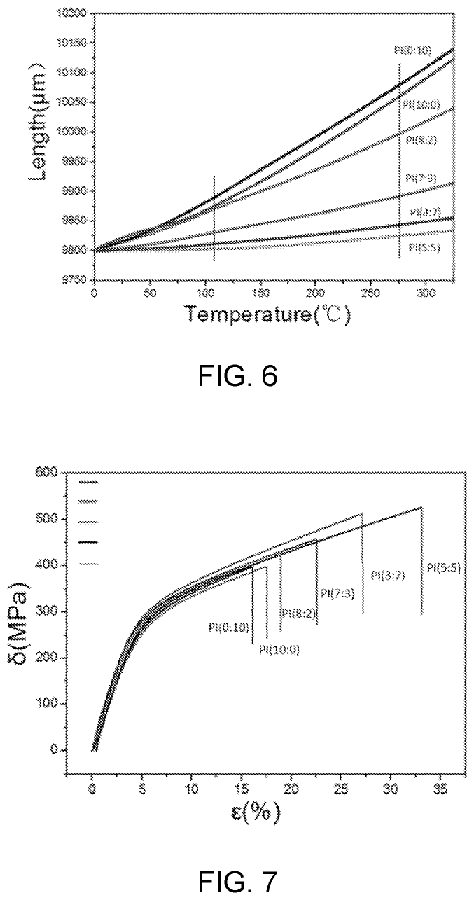

Specifically, reference is made to FIG. 6 which depicts curves of coefficients of thermal expansion of different compounds E obtained from preparation protocols with different proportions of the compound B and the compound C. In FIG. 6, the proportions of the compound B and the compound C are highly associated with the coefficients of thermal expansion of the compounds E, which is finally generated.

For example, when the protocols in which the proportions of the compound B and the compound C are 0:10 and 10:0 are selected for the compounds E, and, that is, the compounds E is synthesized from the single compound B or compound C and the compound A, the single component has a significant influence on the coefficient of thermal expansion of the synthesized compounds E, as specifically shown by the curves of PI (10:0) and PI (0:10) in the figure. The result demonstrates that the ternary system has a desirable effect on reducing the coefficient of thermal expansion of the final generated material, and, that is, both of the compound B and the compound C are preferably included in the preparation raw materials. When the proportion of the compound B and the compound C is 5:5=1, as shown by the curve of PI (5:5) in the figure, a coordination effect of the compound B and the compound C is strongest, to cause high regularity of straight-chains of the target compounds E, so that free volume is difficult to be changed, thereby realizing the low coefficient of thermal expansion.

Furthermore, reference is made to FIG. 7 which depicts stress strain curves of the target compounds E obtained from six protocols with different raw material proportions of the compound B and the compound C in the above examples. As shown in FIG. 7, in the six protocols with different raw material proportions, above 15% of elongation at break of the synthesized target compounds E may be achieved. This value indicates that this parameter of these target compounds E may meet requirements for this indicator of the organic light-emitting diode (OLED) flexible substrates.

Therefore, the introduction of the ternary system is not only conducive to the improvement of the coefficient of thermal expansion, but also conducive to the mechanical performance, which further illustrates that the regular straight-chains improve the crosslink density thereof, thereby achieving the dense cross-linking to realize the desirable mechanical performance. Additionally, another key factor is a transmittance parameter. Because this performance parameter is not convenient to be presented by the graphs, there is no figures. However, it is clear that the transmittance parameters of the compounds E are over 75%, which meets the requirements for the transmittance of all flexible panel substrates in the industry.

A polyimide material involved in the present disclosure employs a newly introduced 2,4-trifluoromethyl dianhydride with benzene rings and fluorine-containing p-phenylenediamine, and the phenylenediamine with the simple binding structure is used to design the molecular structure of the target polyimide material compound. The fluorine-containing group introduced in the molecular structure of the target compound may not only reduce intermolecular force, but also destroy close packing of the polymer to reduce crystallization performance of the polymer, thereby efficiently improving the transmittance performance; besides, the fluorine-containing group may also be used to adjust the rigid structure of the main chain.

Furthermore, the diamine structures with different compactness degrees are obtained by implementing the six proportion protocols of the diamine with different contents in the preparation raw materials, thereby obtaining the relation between the coefficient of thermal expansion and the main chain structure of the target compound. By obtaining the correlation between the coefficient of thermal expansion of the target compound and the rigid structure of the molecular chains, not only may the highly regular arrangement of the target compound be realized, but also the coordinated arrangement of the two diamine molecules may be facilitated, thus rendering the molecular chains compact, to achieve the close packing between the molecular chains. Therefore, the regular structure of the molecular chain of the target compound allows the material per se to present the relatively low coefficient of thermal expansion (CTE) in the CTE performance parameter.

In summary, the dianhydride containing fluorine and benzene rings is selected to be the preparation raw material of the target compound material involved in the present disclosure, thus realizing the desirable transmittance of the final material and improving the mechanical performance of the final material, so that the final material is effectively used for the substrate layer of the OLED display panel. However, it should be understood that the polyimide material involved in the present disclosure is not limited to be used for the substrate of the OLED display panel. The polyimide material may be used for a variety of suitable applications, as long as the performance parameters of the target compound obtained according to different proportion of the raw materials conform to requirements of the applications.

The technical scope of the present disclosure is not only limited to the content of the above description. Those skilled in the art can make various modifications and alterations to the embodiments without departing from the technical spirit of the present disclosure, and all of the modifications and alterations are within the scope of the present disclosure.

1. A polyimide material, comprising a structural formula as shown in the following:

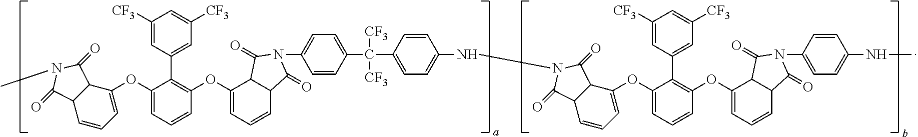

2. The polyimide material according to claim 1, wherein the polyimide material is obtained from its precursor polyamic acid (PAA) through dehydration and cyclization treatment, and a structural formula of the precursor polyamic acid is:

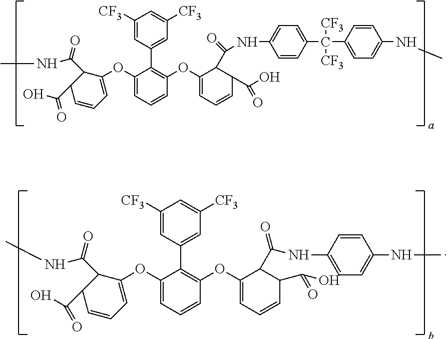

3. The polyimide material according to claim 2, wherein the polyamic acid is prepared by raw materials including a compound A which is 3,5-trifluoromethyl-p-1,3-diether-diphthalic anhydride, a compound B which is 2,4-trifluoromethyl-p-aniline, and a compound C which is phthalic anhydride.

4. The polyimide material according to claim 3, wherein a structural formula of the compound A is: 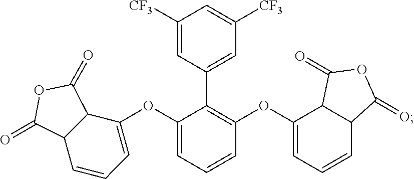 [SMILES: O=C1OC(=O)C2C(Oc3cccc(OC4=CC=CC5C(=O)OC(=O)C45)c3-c3cc(C(F)(F)F)cc(C(F)(F)F)c3)=CC=CC12]
wherein a structural formula of the compound B is:

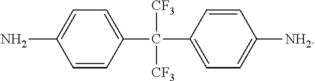 [SMILES: Nc1ccc(C(c2ccc(N)cc2)(C(F)(F)F)C(F)(F)F)cc1]

5. The polyimide material according to claim 3, wherein a molar ratio of the compound A, the compound B, and the compound C is that a molar concentration of the compound A is equal to a sum of a molar concentration of the compound B and a molar concentration of the compound C.

6. The polyimide material according to claim 5, wherein a molar ratio of the compound B and the compound C is a:b ranging from 0:10 to 10:0, and wherein 0≤a≤10, 0≤b≤10, and a+b=10.

7. The polyimide material according to claim 6, wherein a molar ratio of the compound B and the compound C is a:b, and wherein 0<a<10, 0<b<10, and a+b=10.

8. A preparing method for preparing the polyimide material according to claim 1, comprising:
a step S1 of providing preparation raw materials including a compound A which is 3,5-trifluoromethyl-p-1,3-diether-diphthalic anhydride and a compound B which is 2,4-trifluoromethyl-p-aniline, and adding the compound A and the compound B into a mixture of N, N-dimethylhexanamide and N-methylpyrrolidone to form a first mixture solution, followed by starting to stir; providing a compound C which is phthalic anhydride, and adding the compound C into the first mixture solution during stirring to form a second mixture solution; and then continuing stirring at 20-40° C. for 24-96 hours to be fully dissolved;
a step S2 of suction-filtrating the second mixture solution in a vacuum environment, vacuum evacuating a solution obtained after suction-filtrating for 0.8-1.5 hours, removing bubbles in the solution, and then standing the solution at room temperature for 2-4 hours after evacuating, thus obtaining a solution containing precursor polyamic acid; and
a step S3 of dehydrating the solution containing the precursor polyamic acid, and cyclizing the precursor polyamic acid, thus obtaining the polyimide material.

9. A display device, comprising:
a display panel including a polyimide (PI) substrate;
wherein the polyimide (PI) substrate includes a substrate and a polyimide film layer disposed thereon; and
wherein the polyimide film layer includes the polyimide material including a structural formula as shown in the following: [chemical structure]
